(19) United States
(12) Patent Application Publication
(10) Pub. No.: US 2015/0181754 A1
(43) Pub. Date: Jun. 25, 2015

(54) POWER MODULE PACKAGE

(71) Applicant: SAMSUNG ELECTRO-MECHANICS CO., LTD., Suwon-Si (KR)

(72) Inventor: Sung Min SONG, Suwon-Si (KR)

(73) Assignee: SAMSUNG ELECTRO-MECHANICS CO., LTD., Suwon-Si (KR)

(21) Appl. No.: 14/540,040

(22) Filed: Nov. 13, 2014

(30) Foreign Application Priority Data
Dec. 24, 2013 (KR) 10-2013-0162320

(51) Int. Cl. H05K 7/20; H05K 5/06

(52) U.S. Cl. CPC H05K 7/209; H05K 5/069

(57) ABSTRACT

There is provided a power module package. According to an exemplary embodiment of the present disclosure, the power module package includes a lead frame and a heat radiating substrate mounted with power devices and control ICs controlling the power devices, a sealing part made of a sealing resin to expose one surface of the heat radiating substrate to the outside, a first heat sink attached to one surface of the heat radiating substrate, a second heat sink attached to the sealing part to be disposed at an opposite side of the first heat sink; and a connection part connecting between the first and second heat sinks. Therefore, according to the power module package according to the exemplary embodiment of the present disclosure, a heat radiating function is improved, and thus heat radiation related reliability of the power module package may be improved.

### CROSS-REFERENCE TO RELATED APPLICATION

This application claims the foreign priority benefit of Korean Patent Application No. 10-2013-0162320, filed on Dec. 24, 2013, entitled “Power Module Package” which is hereby incorporated by reference in its entirety into this application.

### BACKGROUND

Embodiments of the present disclosure relate to a power module package.

A power module package is disclosed in Patent Document 1. According to Patent Document 1, the power module package includes a power circuit component, a control circuit component, a lead frame, heat sinks, and a sealing resin. Here, the control circuit component is connected to the power circuit component to control chips within the power circuit component.

Further, the lead frame has edges connected to external connection terminals and has a down set formed between the external connection terminals. Further, the lead frame has a first surface to which the power circuit component and the control circuit component are attached and a second surface used as a thermal emission path, and in particular, the power circuit component is attached to the down set.

Meanwhile, the heat sink adheres to the down set in the second surface of the lead frame by an adhesive. Further, the sealing resin encloses the power circuit component, the control circuit component, the lead frame, and a heat radiating substrate but exposes the external connection terminals of the lead frame and one surface of the heat sink to the outside.

[Related Art Document]

[Patent Document]

(Patent Document 1) KR2008-0064771 A

### SUMMARY

An aspect of the present disclosure may provide an improved heat emission structure in a single direction which is disclosed in Patent Document 1.

Another aspect of the present disclosure may provide a power module package capable of easily improving heat radiating efficiency by emitting heat in all directions.

According to an aspect of the present disclosure, a power module package may include: a lead frame and a heat radiating substrate mounted with power devices and control ICs controlling the power devices; a sealing part formed to expose one surface of the heat radiating substrate to the outside; a first heat sink attached to one surface of the heat radiating substrate; a second heat sink attached to the sealing part to be disposed at an opposite side of the first heat sink; and a connection part connecting between the first and second heat sinks.

The connection part may connect between the first and second heat sinks outside the sealing part.

An end of the connection part may be provided with a fastening ring part.

The connection part may be integrally formed with the second heat sink.

The connection part may connect between the first and second heat sinks inside the sealing part.

An outside of the sealing part may be provided with a cavity in which the second heat sink is accommodated.

According to another aspect of the present disclosure, a power module package may include: a lead frame and a heat radiating substrate mounted with power devices and control ICs controlling the power devices; a sealing part formed to expose one surface of the heat radiating substrate to the outside; a first heat sink attached to one surface of the heat radiating substrate; and a second heat sink inserted into a cavity formed inside the sealing part to be disposed at an opposite side of the first heat sink.

The cavity may be formed in a circle, a triangle, or a quadrangle.

The cavity may be formed in a row along a width direction of the sealing part.

### BRIEF DESCRIPTION OF DRAWINGS

The above and other aspects, features and other advantages of the present disclosure will be more clearly understood from the following detailed description taken in conjunction with the accompanying drawings, in which:

FIGS. 1 and 2 are perspective views illustrating a power module package according to a first exemplary embodiment of the present disclosure;

FIG. 3 is a cross-sectional view illustrating the power module package according to the first exemplary embodiment of the present disclosure;

FIGS. 4 and 5 are perspective views illustrating a power module package according to a second exemplary embodiment of the present disclosure;

FIG. 6 is a cross-sectional view illustrating a power module package according to a third exemplary embodiment of the present disclosure;

FIG. 7 is a cross-sectional view illustrating a power module package according to a fourth exemplary embodiment of the present disclosure; and

FIG. 8 is a cross-sectional view illustrating a power module package according to a fifth exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

A power module package according to an exemplary embodiment of the present disclosure includes power devices, control ICs, a lead frame, a heat radiating substrate, a sealing part enclosing them, and heat sinks, in which the heat sinks are attached to the power module package in all directions.

That is, in a general power module package, the heat sink is attached to a single surface of a power module to form a heat emission structure in a single direction. On the other hand, in the power module package according to the exemplary embodiment of the present disclosure, the heat sinks are attached in all directions to form a heat radiating structure, thereby providing more improved heat radiating effect. Therefore, according to the power module package according to the exemplary embodiment of the present disclosure, a heat radiating function is improved, and thus heat radiation related reliability of the power module package may be improved.

Further, the heat sinks attached to the power module package in all directions are configured to connect to each other outside the power module package, and thus the heat radiating function may be more improved thanks to heat conduction.

Meanwhile, in the power module package according to the exemplary embodiment of the present disclosure, the heat sinks are attached to the power module in all directions and a sealing part is formed with a cavity in which the heat sinks are mounted. Here, the cavity is formed outside or inside the sealing part. Therefore, in the power module package according to the exemplary embodiment of the present disclosure, the heat radiating function may be improved without specially increasing a thickness of the power module package.

Hereinafter, an exemplary embodiment of the present disclosure is described hereafter in detail with reference to the accompanying drawings.

### First Exemplary Embodiment

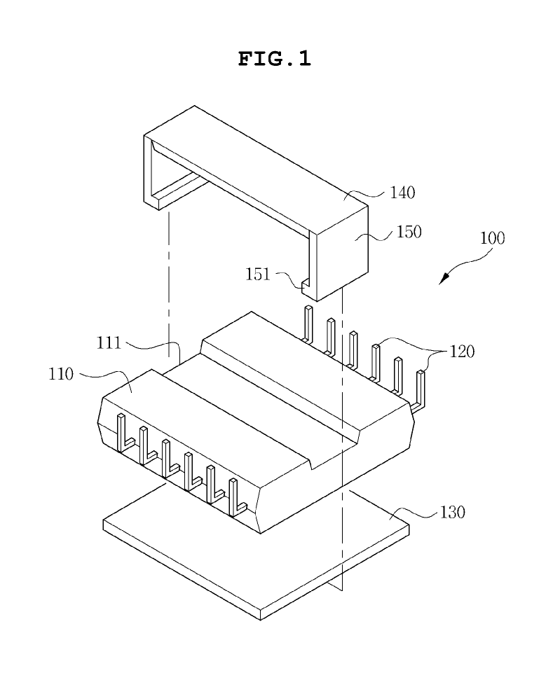

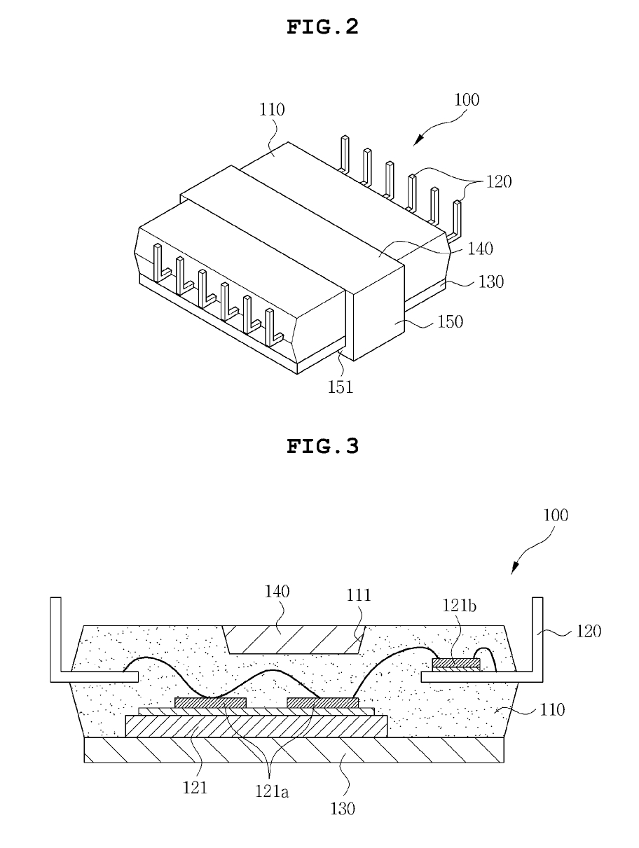

As illustrated in FIGS. 1 and 2, a power module package 100 according to a first exemplary embodiment of the present disclosure is made of a sealing resin and one surface and the other surface of a sealing part 110, that is, an upper portion and a lower portion in FIGS. 1 and 2 from which ends of a lead frame 120 are exposed to the outside are attached with first and second heat sinks 130 and 140. Further, the first and second heat sinks 130 and 140 are connected to each other through a connection part 150 to configure a heat radiating structure in all directions.

Here, the connection parts 150 are integrally formed before and behind the second heat sink 140 in FIGS. 1 and 2 and thus are configured in pair and ends of each of the connection parts are provided with fastening ring parts 151 to be bent toward the first heat sink 130, such that the fastening ring parts 151 are fastened with the first heat sink 130.

That is, the second heat sink 140 is attached to an upper portion of the sealing part 110 and is fastened with an outside of the first heat sink 130 of an opposite side thereto by the fastening ring parts 151 formed at the connection part 150, such that heat conduction is made by the connection.

Further, the upper portion of the sealing part 110 attached with the second heat sink 140 is provided with a bent part 111 as a cavity. In this case, the bent part 111 is formed at the same depth as a thickness of the second heat sink 140. Therefore, heat may be emitted in multi directions without increasing the thickness of the power module package 100 due to the attachment of the second heat sink 140, thereby improving the heat radiating function.

As illustrated in FIG. 3, the first heat sink 130 is attached to one surface of a heat radiating substrate 121 exposed to the outside of the sealing part 110, that is, a lower portion of the heat radiating substrate 121 in FIG. 3. The heat radiating substrate 121 has an upper portion mounted with a power device 121a to emit heat generated from the power device 121a through the first heat sink 130.

A control device 121b electrically connected to the power device 121a through a wire bonding and controlling the power device 121a is mounted on the lead frame 120, in which the lead frame 120 is also wire-bonded to the power device 121a.

Therefore, the power module package 100 according to the first exemplary embodiment of the present disclosure emits heat generated from the power device 121a through the first heat sink 130 and then emits heat through the connection part 150 and the second heat sink 140 thanks to the heat conduction, thereby providing the improved heat radiating function.

### Second Exemplary Embodiment

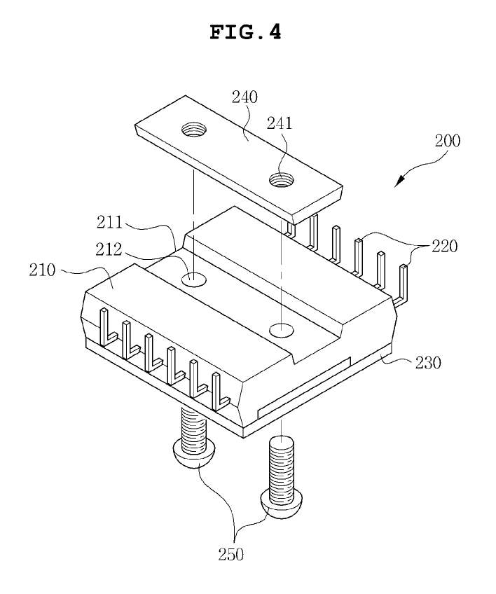

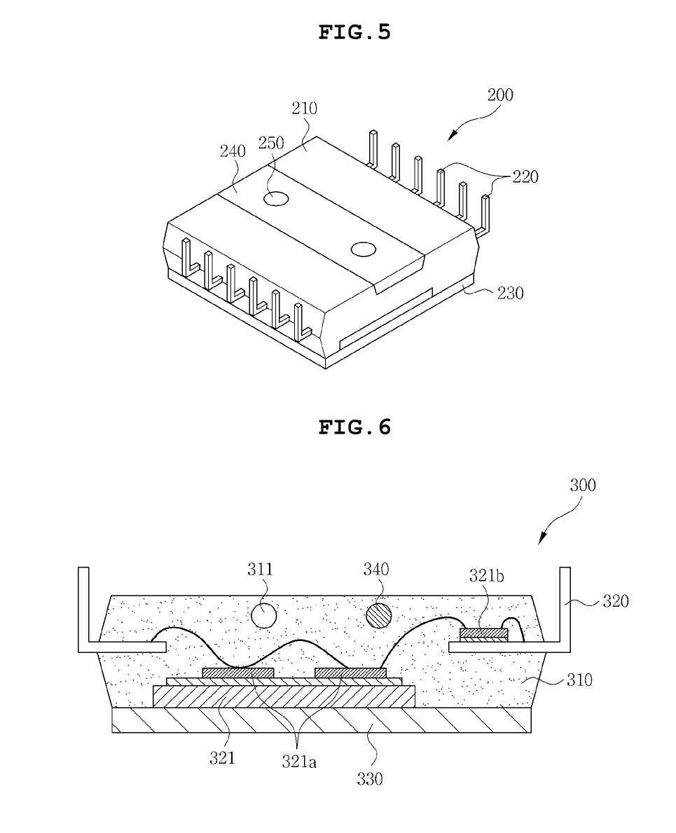

As illustrated in FIGS. 4 and 5, a power module package 200 according to a second exemplary embodiment of the present disclosure is made of a sealing resin and one surface and the other surface of a sealing part 210, that is, an upper portion and a lower portion in FIGS. 4 and 5 from which an end of a lead frame 220 is exposed to the outside are attached with first and second heat sinks 230 and 240. Further, the first and second heat sinks 230 and 240 are connected to each other through a connection part 250 to configure a heat radiating structure in all directions.

Here, an inside of the sealing part 210 is provided with power devices, control ICs, and a heat radiating substrate, along with the lead frame 220 which are electrically connected to one another, but this is the same as the foregoing first exemplary embodiment of the present disclosure and therefore will be omitted.

The connection part 250 uses a general metal bolt and is configured in pair to be fastened before and behind the first and second heat sinks 230 and 240 in FIGS. 4 and 5. Further, the sealing part 210 is provided with a through hole 212 through which the connection part 250 penetrates and a fastening hole 241 fastened with a connection part 250 penetrating through the through hole 212 is formed in the second heat sink 240.

That is, a lower portion of the sealing part 210 attached with the first heat sink 230 is connected to the heat radiating substrate and an upper portion of the sealing part 210 is attached with the second heat sink 240 and then is bolt-fastened with the first heat sink 230 of an opposite side thereof through the connection part 250, such that heat conduction is made by the connection.

Meanwhile, the upper portion of the sealing part 210 attached with the second heat sink 240 is provided with a bent part 211 as a cavity. In this case, the bent part 211 is formed at the same depth as a thickness of the second heat sink 240, such that an increase in a thickness of the power module package 200 due to the attachment of the second heat sink 240 does not occur.

Therefore, the power module package 200 according to the second exemplary embodiment of the present disclosure may emit heat generated from a power device 221a through the first heat sink 230 and then emit heat through the connection part 250 and the second heat sink 240 thanks to the heat conduction, that is, emit heat in multi directions, thereby providing the improved heat radiating function.

### Third Exemplary Embodiment

As illustrated in FIG. 6, a power module package 300 according to a third exemplary embodiment of the present disclosure is made of a sealing resin and one surface of a sealing part 310 from which ends of a lead frame 320 are exposed to the outside is attached with a first heat sink 330. Further, the second heat sink 340 is disposed at an opposite side of the first heat sink 330, while being inserted into a cavity formed in the sealing part 310, thereby configuring the heat radiating structure in all directions.

That is, the first heat sink 330 is attached to a heat radiating substrate 321 exposed to a lower portion of the sealing part 310 in FIG. 6. The heat radiating substrate 321 has an upper portion mounted with a power device 321a to emit heat generated from the power device 321a through the first heat sink 330.

Here, a control device 321b electrically connected to the power device 321a through a wire bonding and controlling the power device 321a is mounted on the lead frame 320, in which the lead frame 320 is also wire-bonded to the power device 321a.

Meanwhile, an inside of the sealing part 310 is provided with a circular cavity 311 into which the second heat sink 340 is inserted. In the case of the circular cavity 311, the second heat sink 340 is formed in an upper portion of the sealing part 310 to be disposed at an opposite side of the first heat sink 330.

Further, the circular cavity 311 is formed in a row along a width direction of the sealing part 310, that is, a horizontal direction of the sealing part 310 in FIG. 6 and thus the second heat sink 340 formed in a circle may be disposed in plural.

Therefore, the power module package 300 according to the third exemplary embodiment of the present disclosure may emit heat generated from the power device 321a through the first heat sink 330 and then emit heat through the plurality of second heat sinks 340 formed in a circle, that is, emit heat in multi directions, thereby providing the improved heat radiating function.

### Fourth Exemplary Embodiment

As illustrated in FIG. 7, a power module package 400 according to a fourth exemplary embodiment of the present disclosure is made of a sealing resin and one surface of a sealing part 410 from which ends of a lead frame 420 are exposed to the outside is attached with a first heat sink 430. Further, the second heat sink 440 is disposed at an opposite side of the first heat sink 430, while being inserted into a cavity formed inside the sealing part 410, thereby configuring the heat radiating structure in all directions.

That is, the first heat sink 430 is attached to a heat radiating substrate 421 exposed to a lower portion of the sealing part 410 in FIG. 7. The heat radiating substrate 421 has an upper portion mounted with a power device 421a to emit heat generated from the power device 421a through the first heat sink 430.

Here, a control device 421b electrically connected to the power device 421a through a wire bonding and controlling the power device 421a is mounted on the lead frame 420, in which the lead frame 420 is also wire-bonded to the power device 421a.

Meanwhile, an inside of the sealing part 410 is provided with a triangular cavity 411 into which the second heat sink 440 is inserted. In the case of the triangular cavity 411, the second heat sink 440 is formed in an upper portion of the sealing part 410 to be disposed at an opposite side of the first heat sink 430.

Further, the triangular cavity 411 may be formed in a row along a width direction of the sealing part 410, that is, a horizontal direction of the sealing part 410 in FIG. 7 to dispose the second heat sink 440 in plural, but is arranged to have a form in which a regular triangle or an inverted triangle is repeated.

Therefore, the power module package 400 according to the fourth exemplary embodiment of the present disclosure may emit heat generated from the power device 421a through the first heat sink 430 and then emit heat through the plurality of second heat sinks 440 formed in a triangle, that is, emit heat in multi directions, thereby providing the improved heat radiating function.

### Fifth Exemplary Embodiment

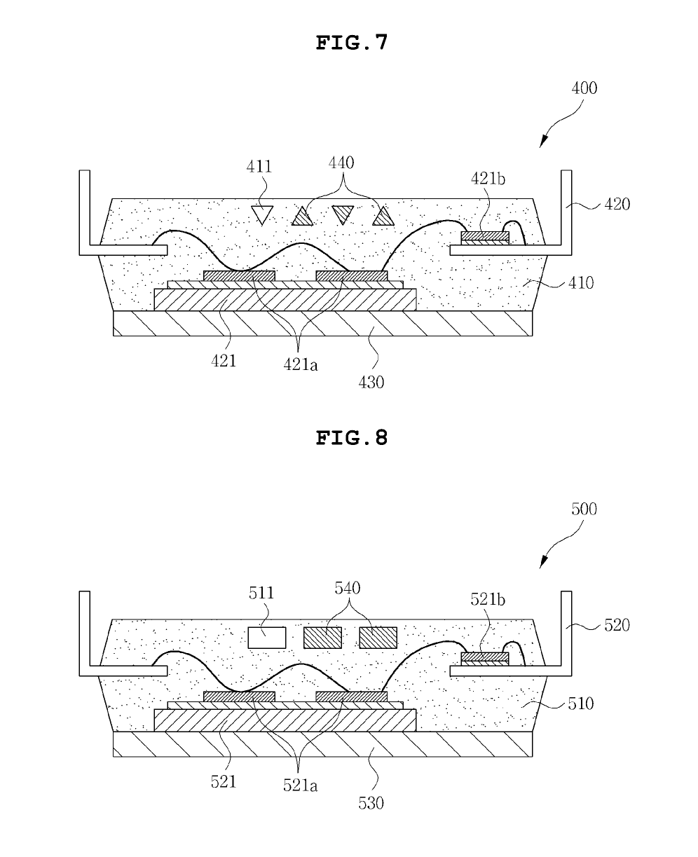

As illustrated in FIG. 8, a power module package 500 according to a fifth exemplary embodiment of the present disclosure is made of a sealing resin and one surface of a sealing part 510 from which ends of a lead frame 520 are exposed to the outside is attached with a first heat sink 530. Further, the second heat sink 540 is disposed at an opposite side of the first heat sink 530, while being inserted into a cavity formed inside the sealing part 510, thereby configuring the heat radiating structure in all directions.

That is, the first heat sink 530 is attached to a heat radiating substrate 521 exposed to a lower portion of the sealing part 510 in FIG. 8. The heat radiating substrate 521 has an upper portion mounted with a power device 521a to emit heat generated from the power device 521a through the first heat sink 530.

Here, a control device 521b electrically connected to the power device 521a through a wire bonding and controlling the power device 521a is mounted on the lead frame 520, in which the lead frame 520 is also wire-bonded to the power device 521a.

Meanwhile, an inside of the sealing part 510 is provided with a quadrangular cavity 511 into which the second heat sink 540 is inserted. In the case of the quadrangular cavity 511, the second heat sink 540 is formed in an upper portion of the sealing part 510 to be disposed at an opposite side of the first heat sink 530.

Further, the quadrangular cavity 511 is formed in a row along a width direction of the sealing part 510, that is, a horizontal direction of the sealing part 510 in FIG. 8 and thus the second heat sink 540 formed in a quadrangle may be disposed in plural.

Therefore, the power module package 500 according to the fifth exemplary embodiment of the present disclosure may emit heat generated from the power device 521a through the first heat sink 530 and then emit heat through the plurality of second heat sinks 540 formed in a quadrangle, that is, emit heat in multi directions, thereby providing the improved heat radiating function.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A power module package, comprising:
a lead frame and a heat radiating substrate mounted with power devices and control ICs controlling the power devices;
a sealing part formed to expose one surface of the heat radiating substrate to the outside;
a first heat sink attached to one surface of the heat radiating substrate;
a second heat sink attached to the sealing part to be disposed at an opposite side of the first heat sink; and
a connection part connecting between the first and second heat sinks.

2. The power module package of claim 1, wherein the connection part connects between the first and second heat sinks outside the sealing part.

3. The power module package of claim 2, wherein an end of the connection part is provided with a fastening ring part.

4. The power module package of claim 3, wherein the connection part is integrally formed with the second heat sink.

5. The power module package of claim 1, wherein the connection part connects between the first and second heat sinks inside the sealing part.

6. The power module package of claim 1, wherein an outside of the sealing part is provided with a cavity in which the second heat sink is accommodated.

7. The power module package of claim 6, wherein the cavity is formed at the same depth as a thickness of the second heat sink.

8. A power module package, comprising:
a lead frame and a heat radiating substrate mounted with power devices and control ICs controlling the power devices;
a sealing part formed to expose one surface of the heat radiating substrate to the outside;
a first heat sink attached to one surface of the heat radiating substrate; and
a second heat sink inserted into a cavity formed inside the sealing part to be disposed at an opposite side of the first heat sink.

9. The power module package of claim 8, wherein the cavity is formed in a circle, a triangle, or a quadrangle.

10. The power module package of claim 8, wherein the cavity is formed in a row along a width direction of the sealing part.
